(19) United States
(12) Patent Application Publication
(10) Pub. No.: US 2025/0385068 A1
(43) Pub. Date: Dec. 18, 2025

(54) BLACK BODY SURFACE GENERATION USING LASER MATERIAL PROCESSING

(71) Applicant: Applied Materials, Inc., Santa Clara, CA (US)

(72) Inventors: Gagandeep Singh Joshi, Fresno, CA (US); Anantha Subramani, San Jose, CA (US); Joseph Frederick Sommers, Couer D'Alene, ID (US); Joseph Frederick Behnke, San Jose, CA (US); Christopher Laurent Beaudry, San Jose, CA (US); Wei-Sheng Lei, San Jose, CA (US)

(21) Appl. No.: 18/742,898

(22) Filed: Jun. 13, 2024

(51) Int. Cl. H01J 37/16; G21F 1/06; G21F 3/00

(52) U.S. Cl. CPC H01J 37/165; G21F 1/06; G21F 3/00; H01J 2237/0266

(57) ABSTRACT

A chamber component of a processing chamber, including a body and a textured surface on at least one surface of the body, where the textured surface includes a lattice structure configured to absorb incident electromagnetic radiation at a plurality of frequencies and a plurality of angles of incidence.

### TECHNICAL FIELD

The present disclosure generally relates to systems and methods for blackbody surface generation. More particularly, the present disclosure relates to systems and methods for black body surface generation for semiconductor manufacturing system using laser material processing.

### BACKGROUND

In semiconductor manufacturing and other types of manufacturing (e.g., for displays, photovoltaics, etc.), many processes generate heat. Thermal management and heat dissipation during such processes can affect the quality of manufactured products. Heat buildup, and improper management of heat, during semiconductor manufacturing can lead to performance degradation and even device failure in the semiconductor devices that are ultimately manufactured.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In one aspect of the disclosure, a chamber component of a processing chamber, comprises a body and a textured surface on at least one surface of the body, wherein the textured surface comprises a lattice structure configured to absorb incident electromagnetic radiation at a plurality of frequencies and a plurality of angles of incidence.

In another aspect of the disclosure, a method includes receiving chamber component of a processing chamber. The method further includes performing laser material processing on at least one surface of the chamber component of the processing chamber to form a textured surface, wherein the textured surface comprises a lattice structure configured to absorb incident electromagnetic radiation at a plurality of frequencies and a plurality of angles of incidence.

In another aspect of the disclosure, a system includes a processing chamber and a susceptor disposed within the processing chamber. In some embodiments, the susceptor comprises a top surface comprising a plurality of pockets, wherein each of the plurality of pockets is configured to receive a substrate, and wherein the top surface comprises a lattice structure configured to absorb incident electromagnetic radiation at a plurality of frequencies and a plurality of angles of incidence.

### BRIEF DESCRIPTION OF THE DRAWINGS

The present disclosure is illustrated by way of example, and not by way of limitation in the figures of the accompanying drawings.

FIG. 1A depicts a cross-sectional view of a processing chamber (e.g., a semiconductor wafer processing chamber), according to some embodiments.

FIG. 1B depicts a sectional view of one embodiment of a processing chamber.

FIG. 2 is a top view of a susceptor, according to some embodiments.

FIG. 3 depicts a hexagonal lattice structure, according to some embodiments.

FIG. 4A is a flow diagram of a method associated with performing laser material processing on a surface of a chamber component to form a lattice structure configured to absorb incident electromagnetic radiation, according to some embodiments.

FIG. 4B flow diagram of a method associated with performing laser material processing on a surface of a chamber component to form a lattice structure configured to absorb incident electromagnetic radiation, according to some embodiments.

FIG. 5 is a schematic of a laser material processing system, according to some embodiments.

### DETAILED DESCRIPTION

In the field of semiconductor manufacturing, precise thermal management can contribute to successful and efficient fabrication processes, including etching, chemical vapor deposition (CVD), physical vapor deposition (PVD), etc. In embodiments, chamber components having surfaces that act as black body surfaces (e.g., that are black body surfaces or that approximate black body surfaces) are provided. In embodiments, laser material processing is performed to form black body surfaces (or approximate black body surfaces) on chamber components. The black body surfaces of the chamber components provide increased thermal performance (e.g., increased heat dissipation, emissivity, etc.) of the chamber components.

Chambers used for manufacturing semiconductor devices generate a significant amount of heat during operation or processing, which can lead to performance degradation and even device failure if not adequately dissipated. The creation of black body surfaces or black body surface approximations (e.g., grey body surfaces) can contribute to the optimization of absorption and emission of thermal radiation during fabrication processes. In other words, adding black body surfaces to chamber components of process chambers may overcome the thermal management constraints that such chamber components traditionally possess by providing enhanced thermal radiation properties, enabling more efficient heat dissipation and maintenance of optimal operating temperatures for manufacturing of devices such as semiconductor components. This can help to ensure uniform temperature regulation across semiconductor substrates (e.g., such as wafers) and keep semiconductor substrates within thermal budgets. These surfaces (e.g., surfaces of various chambers and/or chamber components) can approach the characteristics of black body radiation, leading to enhanced process control and energy efficiency.

Furthermore, black body surfaces and/or black body surface approximations can benefit from longevity and performance consistency because semiconductor manufacturing processes can cause the surfaces to undergo repeated thermal cycling. These coatings must also undergo maintenance (e.g., cleanings, refurbishments, etc.) that lead to degradation over time, such as erosion or material flaking, which can alter the thermal management properties of the surfaces and necessitate frequent refurbishments. The extent of material removal during refurbishments and cleanings can significantly reduce the operational lifespan of these components that have coatings to create black body surfaces or black body approximations.

Excessive heat can shorten the lifespan of semiconductor devices and lead to premature failures, impacting their overall reliability. Black body surfaces extend the longevity of semiconductor components by effectively managing heat, ensuring stable operation and reducing the risk of thermal-induced failures. Semiconductor devices also often encounter performance limitations due to temperature-related constraints. Black body surfaces enable improved performance by efficiently dissipating heat, allowing devices to operate at higher frequencies and handle heavier workloads than they would otherwise be able to handle without thermal throttling. Manufacturers often face limitations on the amount of heat their devices can handle, restricting the overall capabilities of products. By adding black body surfaces to chamber components, thermal budgets may be increased, providing manufacturers with additional thermal headroom to unlock enhanced device capabilities. Providing black body surfaces on chamber components may improve semiconductor device reliability and performance of devices manufactured in process chambers using such chamber components through enhanced thermal management in the processing chamber (e.g., process chamber such as an epitaxy chamber that include a susceptor). By mitigating heat-related issues, use of black body surfaces on chamber component enables semiconductor manufacturers to produce more reliable, high-performing devices, meeting the demands of modern technology applications while reducing costly failure rates and warranty claims.

Prior efforts to create black body or gray body surfaces with specific emissivity and absorption properties (e.g., high emissivity) have involved a variety of techniques, including machining techniques of surface morphologies and/or the application of specialized coatings, and have proved unsuccessful. Such prior efforts have fallen short of target emissivity levels, absorption levels, and/or uniformity in surface pattern. Accordingly, heretofore black body and gray body surfaces have not been successfully produced for chamber components of processing chambers (e.g., as used for semiconductor manufacturing).

For example, techniques like bead blasting, used to create specific microstructures on the surfaces of substrates that are intended to enhance thermal interaction, can introduce variability and damage into the surfaces. These imperfections fall short of the intended emissivity and absorption characteristics and create thermal management inefficiency, impacting the quality of the semiconductor devices produced. Conventional coatings for creating black body surfaces or black body approximations can lack uniformity. Similarly, mechanical modifications to surface topography aimed at improving thermal interactions have also lacked uniformity, leading to uneven heat distribution and compromised device integrity, due to imprecise control over surface morphology.

Aspects and implementations of the present disclosure seek to address the limitations of process chambers by providing systems and methods for black body surface generation in a surface of a chamber component using laser material processing. In some embodiments, the chamber component can include a body of silicon carbide. In some embodiments, by tuning laser material processing parameters, specific morphologies can be created on a surface of a chamber component. In some embodiments, the morphology of the surface can be a hexagonal lattice structure. In some embodiments, each individual hexagon of the hexagonal lattice structure can range from 80 to 120 microns in diameter and from 20 to 70 microns deep. In some embodiments, the surface morphology can determine the emissivity and absorption properties of the surface. In some embodiments, emissivity of up to 0.98 can be achieved.

By using material processing to create morphologies in the surfaces of chamber components, aspects and implementations of the present disclosure can achieve target characteristics of black body radiation. Aspects and implementations of the present disclosure can achieve target emissivity levels, absorption levels, and uniformity in surface pattern, due to increased precision in generating the morphology. Aspects and implementations of the present disclosure can avoid causing excessive damage to the surfaces being processed to create the morphologies. Aspects and implementations of the present disclosure can avoid variability in a surface morphology. Aspects and implementations of the present disclosure can increase thermal management efficiency and increase the quality of the devices produced using process chambers that include chamber components having black body surfaces (or approximate black body surfaces) manufactured via laser material processing. Aspects and implementations of the present disclosure can lead to even heat distribution and heightened device integrity, due to precision in forming surface morphologies that can be achieved using laser material processing.

Furthermore, aspects and implementations of the present disclosure can increase the longevity and performance consistency of chamber components by including black body surfaces and/or black body surface approximations on those chamber components. Such increases in longevity and performance consistency can be achieved even when the chamber components are subjected to repeated thermal cycling. Aspects and implementations of the present disclosure can provide increased longevity for chamber components when compared to traditional chamber components that lack black body surfaces or approximate black body surfaces. By creating black body surfaces or black body approximations in chamber components using laser material processing, erosion and material flaking can be reduced even in the presence of repeated thermal cycling and maintenance procedures. Aspects and implementations of the present disclosure may minimize refurbishments, leading to increased operational lifespans of components having blackbody surfaces or blackbody approximations that are generated using laser material processing.

Aspects and implementations of the present disclosure can enhance heat dissipation in chamber components, allowing for more efficient heat dissipation compared to conventional heat sinks or thermal pastes. This results in increased ability to stay withing thermal budgets of processes and manufactured devices. Aspects and implementations of the present disclosure enable precise and customizable design of black body surfaces. This adaptability ensures optimal thermal management for different types of chamber components, leading to improved functionality. Aspects and implementations of the present disclosure can reduce the risk of thermal-induced failures in manufactured devices, enhancing their reliability and extending their operational lifespan.

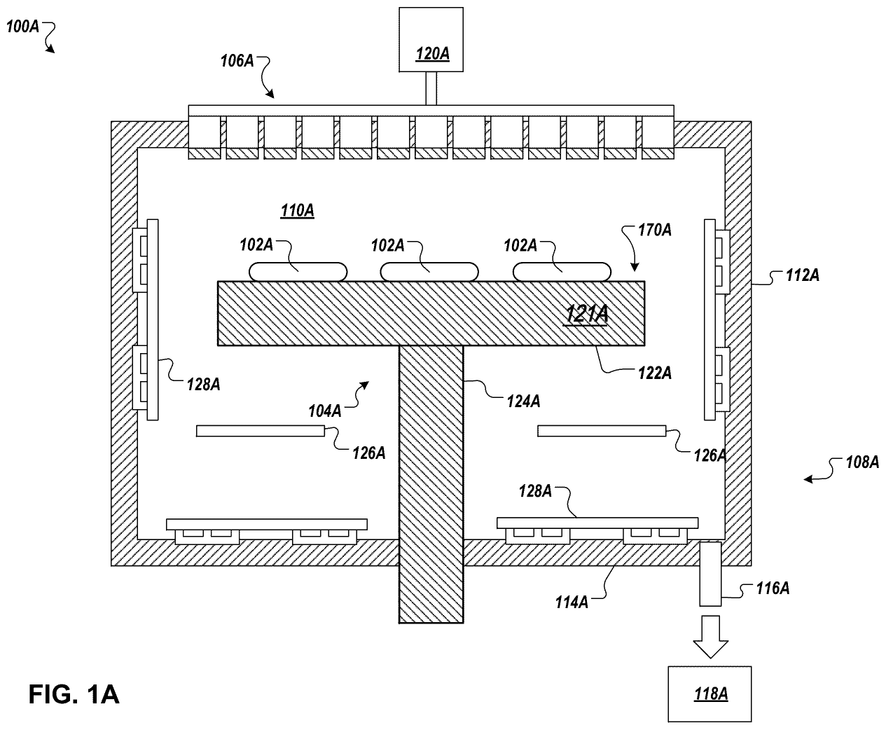

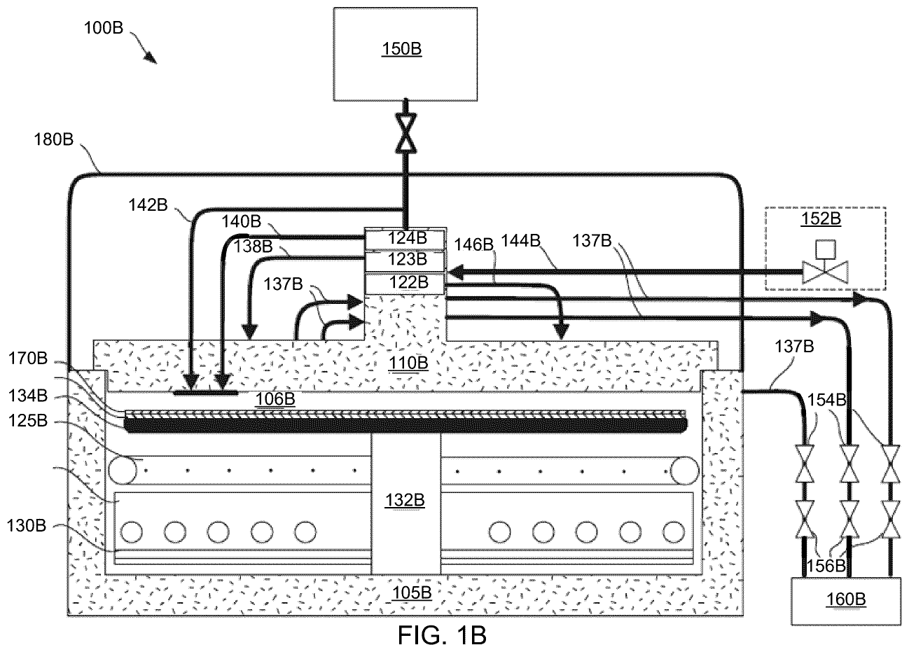

FIG. 1A depicts a sectional view of a processing chamber 100A (e.g., a semiconductor processing chamber), according to some aspects of this disclosure. Processing chamber 100A may be one or more of an etch chamber (e.g., a plasma etch chamber), deposition chamber (including atomic layer deposition, chemical vapor deposition, physical vapor deposition, or plasma enhanced versions thereof), anneal chamber, epitaxy chamber, or the like. For example, processing chamber 100A may be a chamber for a plasma etcher, an epitaxy device, a plasma cleaner, atomic layer deposition (ALD) device, chemical vapor deposition (CVD) device, and so forth. Examples of chamber components may include a substrate support assembly 104A (e.g., a susceptor, an electrostatic chuck, a vacuum chuck, a heater, etc.), a showerhead 106A, a chamber wall, a base, a gas distribution plate, a liner, a liner kit, a shield, a plasma screen, a flow equalizer, a cooling base, a chamber viewport, a chamber lid, a nozzle and so on. Any one or more of these components may be processed to cause them to have a black body surface of an approximate black body surface in embodiments.

In one embodiment, processing chamber 100A may include a chamber body 108A that encloses an interior volume 110A. In some chambers, electromagnetic radiation can be present in the interior volume of 110A of processing chamber 100A. Processing chamber 100A, can employ a variety of electromagnetic radiation sources to facilitate and various fabrication processes. For example, processing chamber 100A can include infrared heaters (e.g., for thermal annealing), ultraviolet light sources (e.g., for photolithography), microwave radiation sources (e.g., for microwave annealing processes), X-ray sources (e.g., for X-ray lithography), lasers sources (e.g., for laser material processing), radio frequency sources (e.g., for plasma generation in plasma etching), etc.

Chamber body 108A may be constructed from aluminum, stainless steel, or other suitable material. Chamber body 108A generally includes sidewalls 112A and a bottom 114A.

In some embodiments, disposed within processing chamber 100A are one or more heaters 126A and/or reflectors 128A.

In some embodiments, a showerhead may be supported on sidewalls 112A of chamber body 108A or on a top portion of the chamber body. The showerhead (or the lid, in some embodiments) may be opened to allow access to interior volume 110A of processing chamber 100A and may provide a seal for processing chamber 100A while closed.

Substrate support assembly 104A may be disposed in interior volume 110A of processing chamber 100A below showerhead 106A. In some embodiments, substrate support assembly 104A includes a susceptor 122A and shaft 124A. In some embodiments, susceptor 122A can be an epitaxy (EPI) susceptor. Substrate support assembly 104A supports one or more substrates 102A during processing. Substrate support assembly 104A may include any support assembly for holding one or more substrates and may include such components as an electrostatic chuck, clamps, edge rings, guide pins, heaters, susceptors, or the like for physically locating, supporting, heating, cooling and/or retaining the substrate. In some embodiments, substrate support assembly 104A is configured for rotation during processing.

An exhaust port 116A may be defined in chamber body 108A and may couple interior volume 110A to a pump system 118A. Pump system 118A may include one or more pumps and valves utilized to evacuate and regulate the pressure of interior volume 110A of processing chamber 100A. An actuator to control gas flow out of the chamber and/or pressure in the chamber may be disposed at or near exhaust port 116A.

Showerhead 106A may be supported on sidewalls 112A of chamber body 108A or on a top portion of the chamber body. Showerhead 106A (or the lid, in some embodiments) may be opened to allow access to interior volume 110A of processing chamber 100A and may provide a seal for processing chamber 100A while closed.

Showerhead 106A may include multiple gas delivery holes throughout. Examples of processing gases that may be used to process substrates in processing chamber 100A may include toxic gases, non-toxic gases, or a combination thereof. For example, the processing gases may include halogen-containing gases, such as C2F6, SF6, SiCl4, HBr, NF3, CF4, CHF3, F2, Cl2, CCl4, BCl3, and SiF4, among others, and other gases such as O2 or N2O. Examples of carrier gases include N2, He, Ar and other gases inert to process gases (e.g., non-reactive gases).

Substrate support assembly 104A may be disposed in interior volume 110A of processing chamber 100A below showerhead 106A. In some embodiments, substrate support assembly 104A includes a susceptor 122A and shaft 124A. Substrate support assembly 104A supports a substrate during processing. In some embodiments, also disposed within processing chamber 100A are one or more heaters 126A and reflectors 128A.

A gas panel may be coupled to processing chamber 100A to provide process or cleaning gases to interior volume 110A through showerhead 106A (or lid and nozzle). The gas panel 120A may be coupled to the processing chamber 100A to provide process and/or cleaning gases via one or more supply line to the interior volume 110A through showerhead 106A.

In some embodiments, an electromagnetic radiation source within a processing chamber can emit controlled wavelengths of electromagnetic radiation, including ultraviolet (UV) light for photolithography, or infrared (IR) radiation for heating processes, etc. In some embodiments, the electromagnetic radiation can catalyze chemical reactions, modify material properties, or pattern intricate designs on semiconductor wafers.

In some embodiments, showerhead 106A receives a remote plasma and directs the remote plasma onto one or more substrates 102A. The plasma may cause the substrates 102A to heat up.

In some embodiments, processing chamber 100A can be used for manufacturing semiconductor devices. Such manufacturing processes can generate a significant amount of heat (e.g., from electromagnetic radiation sources, plasma, etc.) during an operation or processing recipe. Heat buildup in processed substrates can lead to performance degradation and even device failure if not adequately dissipated. In some embodiments, providing black body surfaces having enhanced thermal radiation properties within processing chamber 100A enables more efficient heat dissipation and maintains optimal operating temperatures for substrates in processing chamber 100A. In some embodiments, excessive heat can shorten the lifespan of electronic devices formed on the processed substrates and lead to premature failures, impacting their overall reliability. By using laser material processing to create a black body surface (e.g., a hexagonal lattice structure configured to absorb incident electromagnetic radiation) on a surface of a component of processing chamber 100A, heat can be effectively managed, ensuring stable operation and reducing the risk of thermal-induced failures.

Further, the use of laser material processing to create a black body surface (e.g., hexagonal lattice structure configured to absorb incident electromagnetic radiation) enables improved performance by efficiently dissipating heat, allowing devices to operate at higher frequencies and to handle heavier workloads without thermal throttling. By providing additional thermal budget, enhanced device capabilities are enabled.

In some embodiments, a chamber component of processing chamber 100A such as susceptor 122A includes a body 121A and a textured surface 170A. In some embodiments, the textured surface includes a lattice structure configured to absorb incident electromagnetic radiation. The lattice structure is configured to absorb incident electromagnetic radiation at various frequencies and various angles of incidence. The lattice structure may function as a block body or nearly as a black body in embodiments. In some embodiments, textured surface 170A is an upper surface of susceptor 122A that is configured to support substrate 102A during processing.

In some embodiments, susceptor 122A includes a silicon carbide coating and textured surface 170A is formed in the silicon carbide coating. The textured surface can be configured to behave as a blackbody. For example, textured surface 170A can have thermal properties of a blackbody, enhancing its ability to absorb and emit electromagnetic radiation uniformly. In some embodiments, textured surface 170A can have an emissivity of at least 0.7. In some embodiments, textured surface 170A can have an emissivity ranging from 0.7 to 1.0, close to or equal to that of an ideal blackbody. By behaving as a blackbody, textured surface 170A enables more precise thermal management during processes such as deposition and annealing. By improving the uniformity of temperature across the textured surface 170A of susceptor 122A, process variability can be minimized, leading to fewer defects and higher quality in the final manufactured products.

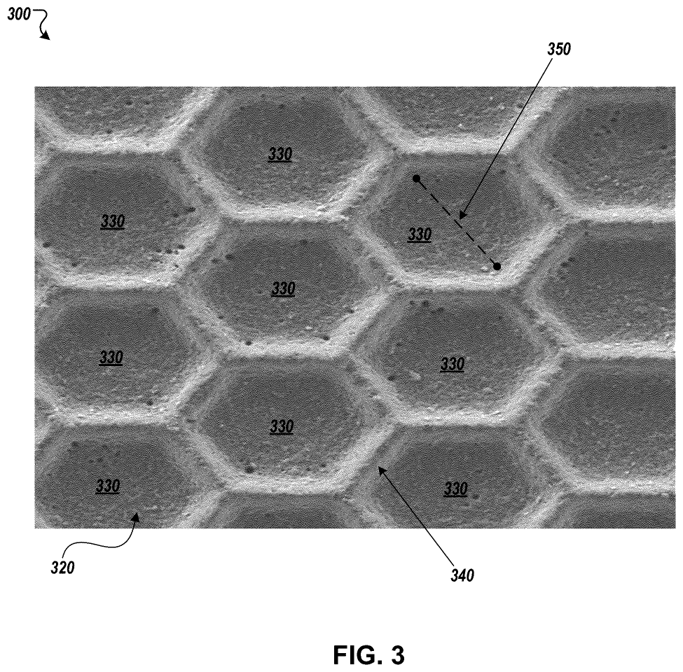

In some embodiments, the lattice structure of textured surface 170A can be a hexagonal lattice structure. The hexagonal lattice structure can include a set of hexagonal cells arranged in a continuous pattern, where each hexagonal cell of the set of hexagonal cells shares at least one sidewall of six sidewalls forming a perimeter of the cell with an adjacent hexagonal cell. For example, each hexagonal cell of the set of hexagonal cells can have a diameter ranging from 80 to 100 microns and a depth ranging from 20 to 60 microns. Further, each hexagonal cell of the set of hexagonal cells is hollow having a substantially flat base. The six sidewalls forming the perimeter of each hexagonal cell of the set of hexagonal cells may be substantially vertical. More details of the hexagonal lattice structure will be given in the description of FIG. 3.

FIG. 1B is a sectional view of a processing chamber according to some aspects of the present disclosure. In some embodiments, the processing chamber 100B may be an ALD processing chamber. In one embodiment, the processing chamber 100B utilizes a remote plasma unit to deliver plasma into the processing chamber 100B for chamber cleaning. Alternatively, other types of processing chambers may be used with embodiments described herein.

The processing chamber 100B may be used for high temperature ALD processes.

In some embodiments, processing chamber 100B can include a susceptor 134B, a chamber body 105B, a showerhead 110B, and so on. In some embodiments, at least one surface of at least one component of processing chamber 100B can include a textured surface 170B, which is described in greater detail below. The textured surface 170B is configured to absorb incident electromagnetic radiation and may include a hexagonal lattice structure in embodiments. As described, the susceptor 134B has a textured surface 170B configured to absorb incident electromagnetic radiation (textured surface 170B), in accordance with some embodiments. However, it should be understood that any of the other chamber components, such as those listed above, may also include a textured surface 170B configured to absorb incident electromagnetic radiation.

In one embodiment, the processing chamber 100B includes a chamber body 105B and a showerhead 110B that enclose an interior volume 106B. The chamber body 105B may be fabricated from aluminum, stainless steel or other suitable material. The chamber body 105B generally includes sidewalls and a bottom. Any of the showerhead 110B, sidewalls and/or bottom may include a textured surface 170B configured to absorb incident electromagnetic radiation.

A chamber exhaust 125B and one or more exhaust ports 137B may vent exhaust out of the interior volume 106B of the chamber. The exhaust ports 137B may be connected to a pump system that includes one or more pumps 160B and throttle valves 156B and/or gate valves 154B utilized to evacuate and regulate the pressure of the interior volume 106B of the processing chamber 100B.

The showerhead 110B may be supported on the sidewalls of the chamber body 105B. The showerhead 110B (or lid) may be opened to allow access to the interior volume 106B of the processing chamber 100B, and may provide a seal for the processing chamber 100B while closed. The showerhead 110B may include a gas distribution plate and one or more injectors 122B, 123B, 124B. The showerhead 110B may be fabricated from aluminum, stainless steel, or other suitable material. Alternatively, the showerhead 110B may be replaced by a lid and a nozzle in some embodiments.

A gas panel 152B may provide process and/or cleaning gases to the interior volume 106B through the showerhead 110B via one or more gas delivery lines 138B-146B. Examples of processing gases that may be used to perform CVD operations to deposit layers on substrates include NH₃, TiCl₄, Tetrakis (dimethylamino) titanium (TDMAT), WF₆, DCS, SiH₄, and so on, depending on the layer to be deposited. For example, a remote plasma source (RPS) 150B may generate Fluorine radicals (F*) during cleaning, and may deliver the Fluorine radicals via one or more gas delivery lines 138B-146B. The gas delivery lines 138B-146B, exhaust ports 137B and showerhead 110B may be covered by a dome 180B, which may be aluminum or another suitable material.

The susceptor 134B is disposed in the interior volume 106B of the processing chamber 100B below the showerhead 110B and supported by a base 132B. The susceptor 134B holds one or more substrates during processing. The susceptor 134B is configured to spin about an axial center during ALD processes so as to ensure the even distribution of process gases interacting with the one or more substrates. Such even distribution improves thickness uniformity of layers deposited on the one or more substrates.

The susceptor 134B is configured to maintain a uniform heat throughout the susceptor 134B during processing. Accordingly, the susceptor 134B may have a body that is composed of a thermally conductive material that has a high resistance to thermal shock. In one embodiment, the body is a semimetal material such as graphite (e.g., coated with SiC or sintered SiC). The susceptor 134B may also have a body composed of other materials with a high thermal shock resistance, such as glass-carbon.

In some embodiments, at least one chamber component of processing chamber 100B can include a hexagonal lattice structure on at least one surface of the component configured to absorb incident electromagnetic radiation.

In some embodiments, for example, susceptor 134B includes a textured surface 170B configured to absorb incident electromagnetic radiation. In some embodiments, the textured surface 170B includes a lattice structure configured to absorb incident electromagnetic radiation. The lattice structure can be configured to absorb incident electromagnetic radiation at various frequencies and various angles of incidence. In some embodiments, susceptor 134B can include a silicon carbide coating and the textured surface 170B can be formed in the silicon carbide coating.

In some embodiments, the textured surface 170B of susceptor 134B can be configured to behave as a blackbody. For example, the textured surface 170B can have thermal properties of a blackbody, enhancing its ability to absorb and emit electromagnetic radiation uniformly. In some embodiments, the morphology of the textured surface 170B can be adjusted to tune the thermal properties of the textured surface 170B (e.g., for chamber matching).

In some embodiments, by behaving as a blackbody, the textured surface 170B of susceptor 134B can enable more precise thermal management during processes such as plasma etching, deposition processes, annealing etc. By improving the uniformity of temperature across the textured surface 170B of susceptor 134B process variability can be minimized, leading to fewer defects and higher quality in the final semiconductor products.

In some embodiments, the lattice structure of the textured surface 170B of susceptor 134B can be a hexagonal lattice structure. The hexagonal lattice structure can include a set of hexagonal cells arranged in a continuous pattern, where each hexagonal cell of the set of hexagonal cells shares at least one sidewall of six sidewalls forming a perimeter of the cell with an adjacent hexagonal cell. For example, each hexagonal cell of the set of hexagonal cells can have a diameter ranging from 80 to 100 microns and a depth ranging from 20 to 60 microns. Further, each hexagonal cell of the set of hexagonal cells is hollow having a substantially flat base. The six sidewalls forming the perimeter of each hexagonal cell of the set of hexagonal cells being substantially vertical. More details of the hexagonal lattice structure will be given in the description of FIG. 3.

The susceptor 134B has multiple depressions. Each depression may be approximately the size of a substrate (e.g., a wafer) that is to be held in the depression. The substrate may be vacuum attached (chucked) to the susceptor 134B during processing.

In one embodiment, one or more heating elements 130B are disposed below the susceptor 134B. One or more heat shields may also be disposed near the heating elements 130B to protect components that should not be heated to high temperatures. In one embodiment, the heating elements 130B are resistive or inductive heating elements. In another embodiment, the heating elements are radiant heating lamps. The heating elements 130B may heat the susceptor 134B to temperatures of up to 700° C. or higher in some embodiments.

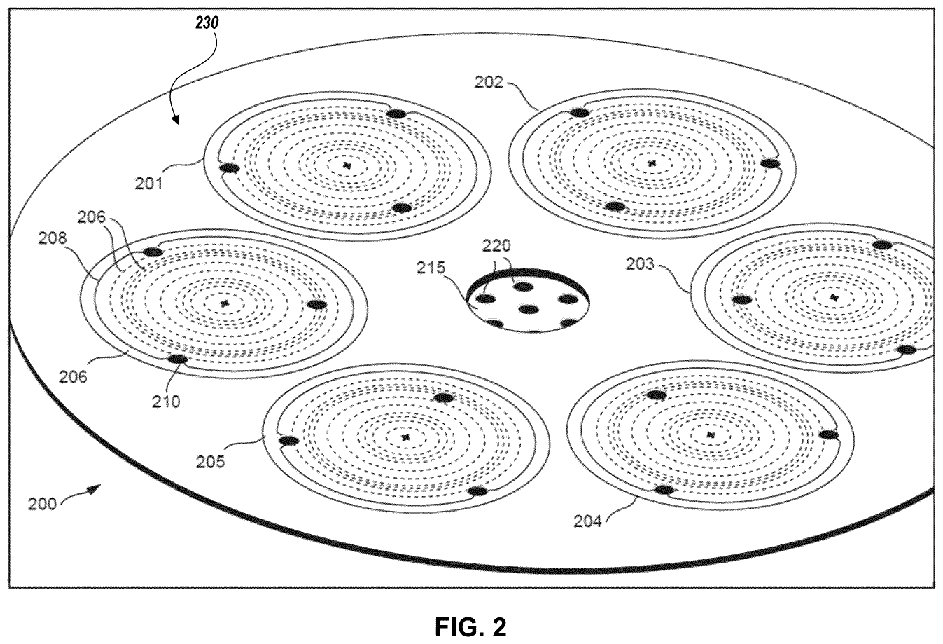

FIG. 2 depicts an example susceptor 200, such as for an ALD chamber. In some embodiments, the susceptor 200 includes a textured surface configured to absorb incident electromagnetic radiation. In one embodiment, a surface of the susceptor 200 includes a silicon carbide coating on an upper surface of the susceptor 200. The susceptor 200 may be made of graphite (e.g., coated with silicone carbide). The textured surface can be a hexagonal lattice structure and the textured surface is formed by the silicon carbide coating. Alternatively, in some embodiments, the silicon carbide coating including the hexagonal lattice structure is on an upper and a lower surface of the susceptor. The silicon carbide coating including the hexagonal lattice structure may also coat side walls of the susceptor. The susceptor 200 may support and uniformly heat and/or cool multiple wafers simultaneously in embodiments.

In one embodiment, the susceptor 200 includes a semimetal thermally conductive base such as graphite. The susceptor 200 may have a disc-like shape that may be large enough to support multiple substrates (e.g., multiple wafers). In one embodiment, the susceptor has a diameter of over 1 meter.

In some embodiments, susceptor 200 includes a top surface 230. The top surface 230 includes a lattice structure configured to absorb incident electromagnetic radiation at various frequencies and a various of angles of incidence. In some embodiments, the top surface 230 includes a silicon carbide coating on the surface, and the silicon carbide coating includes the lattice structure.

In some embodiments, the lattice structure can include a set of hexagonal cells arranged in a continuous pattern, where each hexagonal cell of the set of hexagonal cells shares at least one sidewall of six sidewalls forming a perimeter of the cell with an adjacent hexagonal cell. In some embodiments, the lattice structure is configured to behave as a blackbody.

The susceptor 200 may include one or more depressions (also referred to as pockets) 201-206, each of which may be configured to support a wafer or other substrate during processing. In the illustrated example the susceptor 200 includes 6 depressions 201-206. However, other susceptors may have more or fewer depressions.

Each of the depressions 201-206 includes many surface features. Examples of surface features in depression 201 include an outer ring 208, multiple mesas 206 and channels or gas passages between the mesas 206. The features may have heights of approximately 10-80 microns in some embodiments.

In one embodiment, the susceptor 200 further includes a CVD deposited layer of SiC or SiN over one or more surfaces of the thermally conductive semimetal base. The depressions 201-206 and surface features (e.g., mesas 206 and outer ring 208) may be fluidly coupled to a source of a heat transfer (or backside) gas, such as He via holes drilled in the susceptor 200. In operation, the backside gas may be provided at controlled pressure into the gas passages to enhance the heat transfer between the susceptor 200 and a substrate.

The depressions and surface features may be formed in the body of the susceptor 200 before the silicon carbide coating is deposited. In some embodiments, the depressions and surface features may be formed in the body of the susceptor 200 before the hexagonal lattice structure is formed in the silicon carbide coating. Alternatively, the depressions and/or surface features may be formed in the silicon carbide coating after the silicon carbide coating is deposited thereon. Further, in some embodiments, the depressions and/or surface features may be formed in the hexagonal lattice structure after the hexagonal lattice structure is formed in the silicon carbide coating. The silicon carbide coating may be a conforming coating that conforms to the depressions and surface features.

The susceptor 200 additionally includes lift pin holes 210. For example, the susceptor 200 may include three lift pin holes that support lift pins (e.g., Al₂O₃ lift pins). The lift pins enable the loading and unloading of wafers onto the susceptor 200. Susceptor 200 may include a depression 215 that may be used to clamp the susceptor to a rotating spindle. The depression 215 may include holes 220, which may be used to mechanically fasten the susceptor 200 to the rotating spindle.

FIG. 3 depicts a hexagonal lattice structure 320, according to some embodiments. The hexagonal lattice structure may be formed in surfaces of one or more chamber components to cause those chamber components to act as black bodies in embodiments.

In some embodiments, a textured surface 300 can include the hexagonal lattice structure 320 which can be configured to absorb incident electromagnetic radiation at various frequencies and various of angles of incidence. Textured surface 300 can be, for example, a surface of chamber component such as a susceptor. In some embodiments, the chamber component could be, for example, interior chamber walls, heating elements, wafer chucks, heat shields, reflectors, etc. In some embodiments, the chamber component can be a substrate support, and textured surface 300 can be an upper surface of the substrate support that is configured to support a substrate during processing.

In some embodiments, hexagonal lattice structure 320 can be formed in a silicon carbide coating or other coating on the surface of the chamber component. The coating may be, for example, Al₂O₃, Y₂O₃, SiC, Si—SiC, AlN, Y₃Al₅O₁₂ (YAG), Y₂O₃—ZrO₂, or other materials. Alternatively, the hexagonal lattice structure 320 may be formed in a surface of a body of a chamber component (e.g., that may not include a coating). The body may be formed of aluminum, Al₂O₃, SiC, graphite, Y₂O₃, SiO₂, SiN, Si—SiC, AlN, Y₃Al₅O₁₂ (YAG), Y₂O₃—ZrO₂, or other materials. The textured surface 300 can be configured to behave as a blackbody in order to control thermal management by, for example, helping the supported substrate to stay within a thermal budget.

In some embodiments, hexagonal lattice structure 320 includes a set of hexagonal cells 330 arranged in a continuous pattern. Each hexagonal cell of the set of hexagonal cells 330 shares at least one sidewall of six sidewalls forming a perimeter of the cell with an adjacent hexagonal cell. For example, sidewall 340 is shared by two adjacent hexagonal cells 330 and is one of six sidewalls forming each of the hexagonal cells 330 sharing sidewall 340.

In some embodiments, each hexagonal cell of the set of hexagonal cells 330 can have a diameter (e.g., diameter 350) ranging from 80 to 100 microns. Further, each hexagonal cell of the set of hexagonal cells 330 can have a depth ranging from 20 to 60 microns. Each hexagonal cell of the set of hexagonal cells 330 can be hollow having a substantially flat base. The six sidewalls forming the perimeter of each hexagonal cell of the set of hexagonal cells 330 can be substantially vertical. For example, sidewall 340 is substantially vertical. In some embodiments, textured surface 300 can have an emissivity of at least 0.7. In some embodiments, textured surface 300 can have an emissivity ranging from 0.7 to 1.0, close to or equal to that of an ideal blackbody.

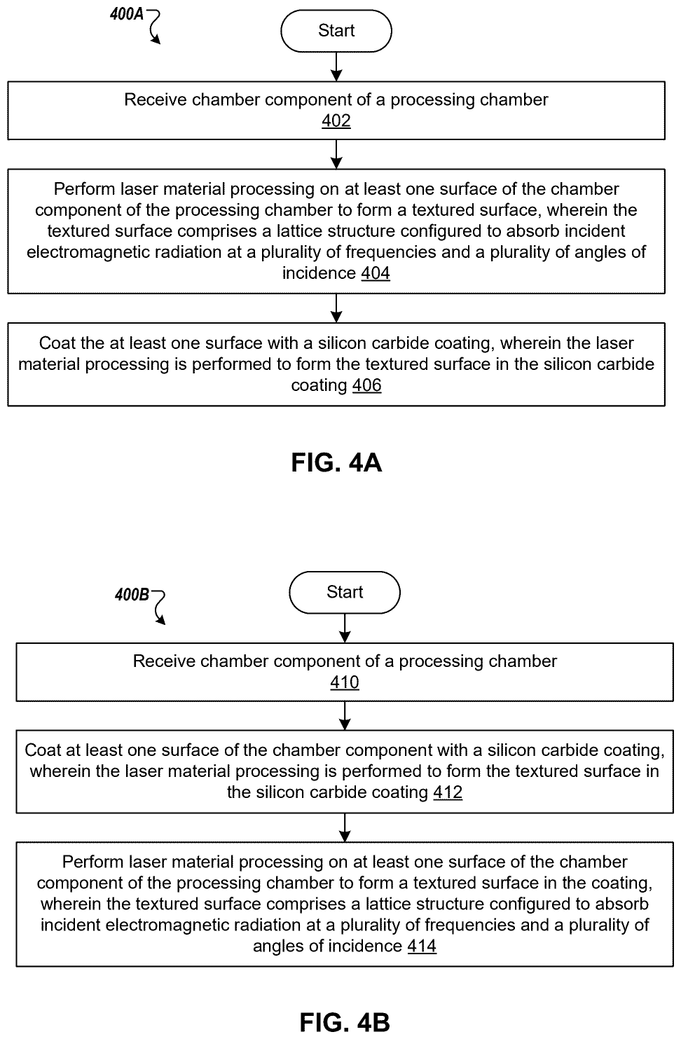

FIG. 4A is a flow diagram of a method 400A for performing laser material processing on a surface of a chamber component to form a lattice structure configured to absorb incident electromagnetic radiation, according to certain embodiments.

Referring to FIG. 4A, in some embodiments, at block 402 processing logic implementing method 400A may cause a chamber component of a processing chamber to be received at a laser material processing station or tool. In an embodiment, a robot arm places the chamber component at a laser material processing station. Alternatively, the chamber component may be manually placed at a laser material processing station.

At block 404, the processing logic causes laser material processing to be performed on at least one surface of the chamber component of the processing chamber to form a textured surface. In some embodiments, the textured surface includes a lattice structure configured to absorb incident electromagnetic radiation at various frequencies and various angles of incidence. In some embodiments, the textured surface is configured to behave as a blackbody. In some embodiments, the lattice structure includes a hexagonal lattice structure. In some embodiments, the lattice structure can include a square lattice (e.g., a grid pattern). In some embodiments, the lattice structure can include other lattice structures such as pentagonal lattices, octagonal lattices, dodecagonal lattice, mixed shape lattices, triangular lattices, rectangular lattices, diamond lattices, Kagome lattices, etc.

In some embodiments, altering the surface morphology of the at least one surface of the chamber component can significantly influence how it interacts with various types of radiation, such as light, infrared, or other electromagnetic waves. For example, by engineering microstructures or nanoscale patterns on the at least one surface of the chamber component, the material's ability to scatter, absorb, or reflect specific wavelengths of light can be tuned. Additionally, modifying the at least one surface of the chamber component to create specific geometric patterns (e.g., a hexagonal lattice structure) can also tailor the emission properties of the at least one surface, making it more effective for infrared thermal management by optimizing the radiation heat transfer.

At block 406, the processing logic causes the at least one textured surface to be coated with a silicon carbide coating (or another coating). The coating may be deposited, for example by chemical vapor deposition (CVD), plasma enhanced CVD, physical vapor deposition (PVD), molecular beam epitaxy (MBE), pulsed laser deposition, sol-gel, or thermal spraying. In some embodiments, the laser material processing of block 404 is performed to form the textured surface in the silicon carbide coating.

In some embodiments, the hexagonal lattice structure includes a set of hexagonal cells arranged in a continuous pattern. For example, each hexagonal cell of the set of hexagonal cells can share at least one sidewall of six sidewalls forming a perimeter of the cell with an adjacent hexagonal cell (e.g., forming a honeycomb like structure). Each hexagonal cell of the set of hexagonal cells can have a diameter ranging from 80 to 100 microns and a depth ranging from 20 to 60 microns. Further, each hexagonal cell of the set of hexagonal cells can be hollow having a substantially flat base. The six sidewalls forming the perimeter of each hexagonal cell of the set of hexagonal cells are substantially vertical. In some embodiments, textured surface as described can have an emissivity of at least 0.7. In some embodiments, textured surface can have an emissivity ranging from 0.7 to 1.0, close to or equal to that of an ideal blackbody.

In some embodiments, the laser material processing enables precise and customizable design of black body surfaces. For example, the morphology of the textured surface can be changed by adjusting parameters of the laser material processing to customize properties of the textured surface such as absorption and emissivity.

Laser material processing involves the use of focused laser beams to modify, cut, weld, or otherwise alter the properties of various materials. The process works through the interaction between the intense light of the laser and the material being processed. In laser material processing, laser light is generated by exciting atoms or molecules within a laser medium, such as a gas, solid-state crystal, or semiconductor. This excitation causes the atoms to emit photons in a coherent, narrow beam of light. The laser beam is typically focused using lenses or mirrors to concentrate its energy into a small spot to achieve high power density and precision in the material processing.

When the focused laser beam interacts with the material, several processes can occur depending on the properties of both the laser and the material. Examples of processes include absorption, melting, vaporization, annealing, hardening, and chemical reactions. For examples, at high power densities, the absorbed energy of the laser can cause the processed material to melt or even vaporize. This is particularly useful for processes like laser cutting and drilling. Laser material processing often involves precise control of parameters such as laser power, pulse duration, pulse energy, focal length, repetition rate, beam scanning speed, etc. Monitoring systems may be employed to ensure consistent quality and accuracy in the processed parts. Laser material processing may be performed by moving a laser source and/or a chamber component being processed (e.g., by a support bed that may be movable in x, y and/or z. In some embodiments, the laser beam may have a fixed direction (e.g., may be vertical). In some embodiments, the direction of the laser beam may be variable, such as by rotating a laser source.

In some embodiments, the scanning pattern and speed are adjusted to ensure uniform and consistent material processing, resulting in a well-defined black body surface structure. By implementing an efficient cooling system to manage heat effects during laser material processing, stable temperatures can be maintained. Proper material handling, clamping, or fixturing can help to ensuring consistency and safety. Incorporation of sensors or monitoring systems can track the laser material processing in real-time, enabling closed-loop feedback systems that can adjust laser parameters dynamically, ensuring the creation of black body surfaces with the desired thermal radiation properties.

In some embodiments, a high-powered laser beam can be focused onto the at least one surface of the chamber component, which alters the surface characteristics. During the laser material processing, specific patterns or structures are created on the semiconductor surface. These patterns are designed to have characteristics of a black body, which is an idealized object that absorbs and emits all incident thermal radiation with maximum efficiency. In some embodiments, the black body surfaces generated by laser material processing enables exceptional thermal radiation properties. During semiconductor manufacturing processes that generate heat, the black body surface efficiently absorbs and emits thermal radiation, leading to more effective heat dissipation (e.g., directing damaging heat away from the substrate).

In some embodiments, using laser material processing to create textured surfaces with black body characteristics allows for precise and customizable design of black body surfaces. For example, the patterns and structures formed on the surfaces can be adjusted based on the specific requirements of the thermal budget of a process recipe, ensuring optimal thermal management.

In some embodiments, the chamber component surface can be cleaned. In some embodiments, a layer of material can be applied to surface to enhance the laser-material interaction. For example, the layer of material can be a materials with specific optical properties that can absorb laser energy more efficiently than the underlying substrate, leading to enhanced precision and effectiveness in laser material processing. Following the preparation of the chamber component surface, the laser material processing is performed on the chamber component. For example, a high-powered laser can be directed onto the surface, and the laser parameters (e.g., intensity, duration, scanning speed, etc.) are precisely controlled to create the desired texture (e.g., a hexagonal lattice structure with black body characteristics). The laser interaction with the semiconductor material alters the surface of the chamber component as well as its absorption and emissivity properties, resulting in the formation of a black body surface.

In some embodiments, after the laser material processing, the black body surfaces can be inspected and tested for accuracy and quality, ensuring that the thermal radiation properties meet the required specifications. The chamber component can then semiconductor components with the black body surface can then be integrated into the processing chamber for use in semiconductor manufacturing processes. The chamber component can be utilized in various processing operations and process recipes.

In some embodiments, laser material processing involves the use of focused laser beams to modify, cut, weld, or otherwise alter the properties of various materials. The process works through the interaction between the intense light of the laser and the material being processed. In laser material processing, laser light is generated by exciting atoms or molecules within a laser medium, such as a gas, solid-state crystal, or semiconductor. This excitation causes the atoms to emit photons in a coherent, narrow beam of light. The laser beam is typically focused using lenses or mirrors to concentrate its energy into a small spot to achieve high power density and precision in the material processing.

After the laser material processing, quality control tools such as microscopy, thermal imaging cameras, or other inspection methods may be used to examine the black body surface created on the at least one surface of the chamber component. These tools can help to ensure the accuracy and quality of the thermal radiation properties of the surface of the chamber component.

FIG. 4B flow diagram of a method associated with performing laser material processing on a surface of a chamber component to form a lattice structure configured to absorb incident electromagnetic radiation, according to some embodiments.

Referring to FIG. 4B, in some embodiments, at block 410 the processing logic implementing method 400B may cause a chamber component of a processing chamber to be received at a laser material processing station or tool. In an embodiment, a robot arm places the chamber component at a laser material processing station. Alternatively, the chamber component may be manually placed at a laser material processing station.

At block 412, the processing logic causes at least one surface of the chamber component of the processing chamber to be coated with a silicon carbide coating. In some embodiments, laser material processing is performed to form a textured surface in the silicon carbide coating.

At block 414, the processing logic causes laser material processing to be performed on the at least one surface of the chamber component of the processing chamber to form a textured surface in the coating. In some embodiments, the textured surface include a lattice structure configured to absorb incident electromagnetic radiation at a plurality of frequencies and a plurality of angles of incidence.

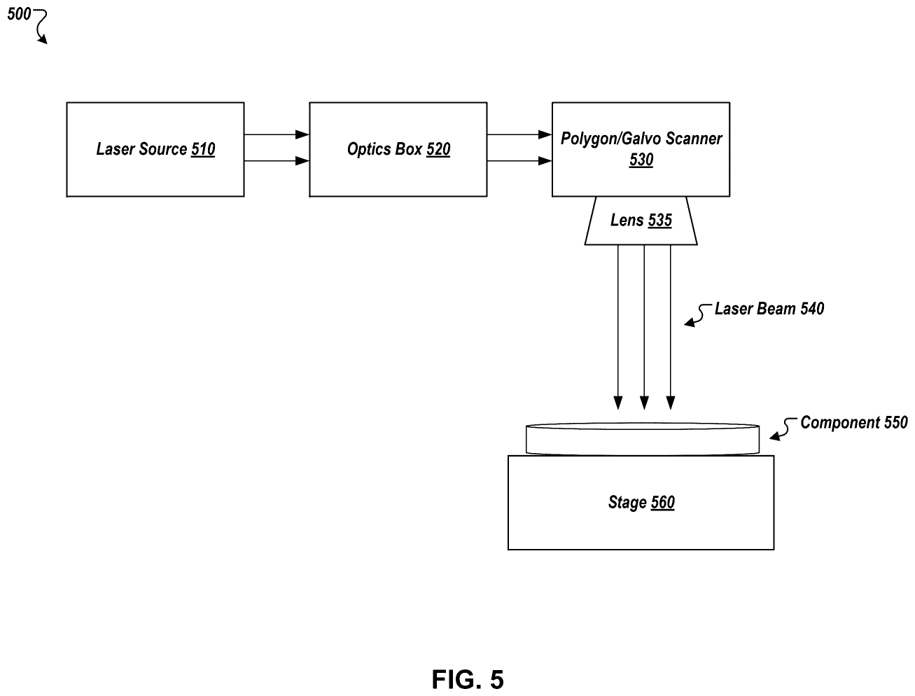

FIG. 5 is a schematic of a laser material processing system 500, according to some embodiments.

In some embodiments, laser material processing system 500 includes a laser source 510. In some embodiments, laser source 510 can be a continuous wave (CW) laser (e.g., a CW CO₂ laser or a CW green laser). In some embodiments, a CW green or blue laser, can be controlled via spot size, power, scanning speed and number of pulses. Laser source 510 generates a coherent beam of light that is directed into an optics box 520. In some embodiments, optics box 520 shapes and focuses the beam of light using an array of mirrors and lenses to precisely control the beam's path and focus. The laser beam is directed into a scanner 530, which dynamically steers the beam across the target surface. This allows for rapid and precise adjustments of the beam's position, enabling intricate cutting, engraving, or marking patterns on a work surface of a component 550. In some embodiments, scanner 530 can be a polygon or galvo scanner.

In some embodiments, a lens 535 (e.g., an F-theta lens) is used in conjunction with scanner 530 to maintain focus and ensure a consistent spot size across the entire scanning field. Lens 535 can correct for the non-linear movements of the scanner, enabling precise and uniform application of the laser beam on the work surface.

In some embodiments, the laser material processing system uses a quarter waveplate.

In some embodiments, a high frequency, ultrashort pulsed laser can be used. Laser material processing may be performed by moving laser beam 540 and/or chamber component 550 being processed (e.g., by a stage 560 that may be movable in an x, y and/or z direction. In some embodiments, the laser beam 540 may have a fixed direction (e.g., may be vertical). In some embodiments, the direction of the laser beam 540 may be variable, such as by rotating a laser source or by adjusting the laser with scanner 530. In some embodiments, the laser is suitable for interaction with semiconductor materials (e.g., silicon carbide), enabling the laser material processing.

In some embodiments, to facilitate the laser material processing, a stable and adjustable stage 560 is can be used to secure and position the chamber component 550. This holder allows for proper alignment and positioning during the laser material processing.

In some embodiments, the laser material processing system 500 uses a focal length ranging from 70 mm to 255 mm. In laser material processing focal length of the laser optics can determine the size of the laser spot (spot size) and the intensity of the beam at the material surface. For example, a shorter focal length produces a smaller spot size with higher intensity, suitable for fine, precise cuts and detailed engravings. Conversely, a longer focal length results in a larger spot size, which is ideal for processes that require broader heat treatment across larger surface areas. Adjusting the focal length allows for precise control over the beam characteristics.

In some embodiments, a high-powered laser beam can be generated using advanced laser sources such as Neodymium-doped Yttrium Aluminum Garnet (Nd: YAG), fiber, or diode lasers. The laser source can be directed through optical elements to achieve specific beam characteristics, including intensity, focus, and spot size. The focused laser beam can interact with the surface of the chamber component 550. This interaction induces various effects based on the material's properties and the laser's characteristics, including absorption, reflection, transmission, melting, vaporization, and ablation. Laser-material interaction induces thermal effects, leading to localized heating and cooling. These thermal effects cause material modification, such as melting, solidification, annealing, or phase changes, depending on the material and laser parameters. The induced thermal effects cause material modification, allowing for cutting, welding, drilling, engraving, surface texturing, and other desired changes in the material's properties or shape.

In some embodiments, laser material processing provides high precision and control, enabling micrometer-scale feature sizes and intricate designs, making it a suitable technique for achieving specific thermal radiation properties in the creation of black body surfaces. In some embodiments, control and monitoring systems are used to manage the laser parameters accurately. These systems enable precise adjustment of laser intensity, duration, scanning speed, and other relevant parameters to achieve the desired black body surface structures.

Laser material processing includes selection of appropriate laser parameters, including wavelength, power, pulse duration, repetition rate, and scanning speed, based on the semiconductor material type, thickness, and desired thermal radiation properties. In some embodiments, the focus and spot size of the laser beam can be fine-tuned to achieve the desired precision and depth of material interaction, ensuring efficient heat dissipation characteristics of the black body surfaces.

In some embodiments, the scanning pattern and speed can be adjusted to ensure uniform and consistent material processing, resulting in a well-defined black body surface structure. By implementing an efficient cooling system to manage heat effects during laser material processing, stable temperatures can be maintained. Proper material handling, clamping, or fixturing can help to ensuring consistency and safety. Incorporation of sensors or monitoring systems can track the laser material processing in real-time, enabling closed-loop feedback systems that can adjust laser parameters dynamically, ensuring the creation of black body surfaces with the desired thermal radiation properties. During manufacturing processes that generate heat, the black body surface efficiently absorbs and emits thermal radiation, leading to more effective heat dissipation (e.g., directing damaging heat away from the substrate).

In some embodiments, a comprehensive evaluation of the processed semiconductor components is performed to assess the quality of the black body surfaces, including dimensional accuracy, surface roughness, and thermal radiation efficiency. Such evaluation results can be analyzed and the optimization process can be iterated to continuously improve the efficiency and quality of creating black body surfaces.

In performing laser material processing, rastering may be used. Rastering can refer to techniques of moving a laser beam in a pattern (e.g., a back-and-forth pattern) across a surface of a material to modify the material according to a specific design, such as in engraving or additive manufacturing. In some embodiments, rastering movement can be achieved through galvanometer (galvo) systems and/or movable wedge systems. Galvo systems can utilize fast-moving mirrors mounted on galvanometers to swiftly direct a laser beam in a desired pattern. Movable wedge systems can involve the physical movement of either the laser head or the material itself (e.g., through linear actuators or motors) to create the raster pattern. In some embodiments, a scan head of a laser material processing system may include an F-Theta lens to yield a specified beam spot size.

In laser material processing, hatch distance can refer to the spacing between adjacent raster lines, dictating the application density of a laser on a material and influencing the engraving depth, surface smoothness, and energy input. In some embodiments, a smaller hatch distance can result in greater overlap of laser paths for a more uniform treatment, whereas a larger distance allows for quicker processing with less intensity. In some embodiments, hatch type can describe the pattern or direction of the raster lines. For example, single-directional, where the laser moves back and forth in one direction, or cross-hatched patterns that apply laser paths in two perpendicular directions for even coverage. In some embodiments, by tuning laser material processing parameters while following a rastering pattern, kinking in features can be reduced. For example, where a rastering pattern overlaps the laser can be momentarily turned off so the intersection is not processed twice creating a deeper engraving than desired.

In some embodiments, using laser material processing to create textured surfaces with black body characteristics allows for precise and customizable design of black body surfaces. For example, the patterns and structures formed on the surfaces can be adjusted based on the specific requirements of the thermal budget of a process recipe, ensuring optimal thermal management. In some embodiments, a laser material processing system can be used to perform the laser material processing.

Examples described herein also relate to an apparatus for performing the methods described herein. This apparatus may be specially constructed for performing the methods described herein, or it may include a general purpose computer system selectively programmed by a computer program stored in the computer system. Such a computer program may be stored in a computer-readable tangible storage medium.

The methods and illustrative examples described herein are not inherently related to any particular computer or other apparatus. Various general purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

What is claimed is:

1. A chamber component of a processing chamber, comprising:
a body; and
a textured surface on at least one surface of the body, wherein the textured surface comprises a lattice structure configured to absorb incident electromagnetic radiation at a plurality of frequencies and a plurality of angles of incidence.

2. The chamber component of claim 1, wherein the chamber component comprises a susceptor.

3. The chamber component of claim 1, wherein the chamber component comprises a substrate support, and wherein the at least one surface comprises an upper surface of the substrate support that is configured to support a substrate during processing.

4. The chamber component of claim 1, further comprising:
a silicon carbide coating on the at least one surface, wherein the silicon carbide coating comprises the textured surface.

5. The chamber component of claim 1, wherein the textured surface is configured to behave as a blackbody.

6. The chamber component of claim 1, wherein the lattice structure comprises a hexagonal lattice structure.

7. The chamber component of claim 6, wherein the hexagonal lattice structure comprises a plurality of hexagonal cells arranged in a continuous pattern, and wherein each hexagonal cell of the plurality of hexagonal cells shares at least one sidewall of six sidewalls forming a perimeter of the cell with an adjacent hexagonal cell.

8. The chamber component of claim 7, wherein each hexagonal cell of the plurality of hexagonal cells comprises a diameter ranging from 80 to 100 microns.

9. The chamber component of claim 7, wherein each hexagonal cell of the plurality of hexagonal cells comprises a depth ranging from 20 to 60 microns.

10. The chamber component of claim 7, wherein each hexagonal cell of the plurality of hexagonal cells is hollow having a substantially flat base.

11. The chamber component of claim 7, wherein the six sidewalls forming the perimeter of each hexagonal cell of the plurality of hexagonal cells are substantially vertical.

12. The chamber component of claim 1, wherein the textured surface has an emissivity of at least 0.7.

13. A method comprising:
receiving chamber component of a processing chamber; and
performing laser material processing on at least one surface of the chamber component of the processing chamber to form a textured surface, wherein the textured surface comprises a lattice structure configured to absorb incident electromagnetic radiation at a plurality of frequencies and a plurality of angles of incidence.

14. The method of claim 13, wherein the textured surface is configured to behave as a blackbody.

15. The method of claim 13, wherein the lattice structure comprises a hexagonal lattice structure.

16. The method of claim 13, further comprising:
coating the at least one surface with a silicon carbide coating, wherein the laser material processing is performed to form the textured surface in the silicon carbide coating.

17. A system comprising:
a processing chamber; and
a susceptor disposed within the processing chamber, the susceptor comprising:
a top surface comprising a plurality of pockets, wherein each of the plurality of pockets is configured to receive a substrate, and wherein the top surface comprises a lattice structure configured to absorb incident electromagnetic radiation at a plurality of frequencies and a plurality of angles of incidence.

18. The system of claim 17, wherein the top surface comprises a silicon carbide coating on the surface, and wherein the silicon carbide coating comprises the lattice structure.

19. The system of claim 18, wherein the lattice structure comprises a plurality of hexagonal cells arranged in a continuous pattern, and wherein each hexagonal cell of the plurality of hexagonal cells shares at least one sidewall of six sidewalls forming a perimeter of the cell with an adjacent hexagonal cell.

20. The system of claim 17, wherein the lattice structure is configured to behave as a blackbody.
